(19) United States
(12) Patent Application Publication
(10) Pub. No.: US 2009/0009057 A1
(43) Pub. Date: Jan. 8, 2009

(54) QUANTUM DOT OPTICAL DEVICE

(75) Inventors: Eun Kyung LEE, Suwon-si (KR); Jong Min KIM, Suwon-si (KR); Byoung Lyong CHOI, Seoul (KR); Kyung Sang CHO, Gwacheon-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/032,252

(22) Filed: Feb. 15, 2008

(30) Foreign Application Priority Data
Jul. 6, 2007 (KR) 10-2007-0068000

(51) Int. Cl. H01J 1/63; H01L 31/0336

(52) U.S. Cl. 313/503; 257/14; 257/E31.005

(57) ABSTRACT

Disclosed herein is a quantum dot optical device, including: a substrate; a hole injection electrode; a hole transport layer; a quantum dot luminescent layer; an electron transport layer; and an electron injection electrode, wherein a light-emitting surface of the device has a periodical projection structure.

### CROSS-REFERENCE TO RELATED PATENT APPLICATIONS

This application claims priority to Korean Patent Application No. 10-2007-0068000, filed on Jul. 6, 2007, and all the benefits accruing therefrom under 35 U.S.C. §119, the content of which is incorporated herein by reference in its entirety.

### BACKGROUND OF THE INVENTION

1. Field of the Invention

Example embodiments relate to a quantum dot optical device including a substrate, a hole injection electrode, a hole transport layer, a quantum dot luminescent layer, an electron transport and an electron injection electrode, which can amplify light in a specific wavelength band because the device has a periodic projection structure on the light-emitting surface thereof, and which has high-efficiency and high-purity light-emitting properties or light-receiving properties.

2. Description of the Related Art

An electroluminescence device is a device manufactured using the phenomenon by which light is emitted when an electric field is applied to a material. In the electroluminescent device, electrons and holes injected into a luminescent layer are formed into excitons, and then light is emitted due to the recombination of the excitons. Recently, a large number of devices, which use a quantum dot as a luminescent layer, have been developed.

A quantum dot is a nano-sized semiconductor material and exhibits a quantum confinement effect. This quantum dot receives light from an excitation source, reaches an energy excitation state, and then emits energy due to the band gap of energy. Therefore, this quantum dot is applied to various devices, such as light-receiving devices, light-emitting devices, and the like, because the electrical and optical characteristic of devices can be adjusted by controlling the size of quantum dot.

Korean Unexamined Patent Publication No. 10-2006-0027133 discloses a light-emitting diode and a method of manufacturing the light-emitting diode by epitaxially growing a nitride semiconductor material, such as GaN. It is disclosed in the patent document that, when a semiconductor layer is etched depending on patterns and protrusions are thus formed thereon, a quantum dot having higher energy density than that of a planar surface is formed on the inclined surface thereof. The invention disclosed in the patent document is effective in that the light-emitting area of the diode is increased due to the inclined surface thereof, but has a problem in that the density and arrangement of quantum dots is not easily adjusted because an epitaxial growing method is used to form a quantum dot in order to obtain the light-emitting properties of the diode.

### SUMMARY OF THE INVENTION

Accordingly, example embodiments have been made to overcome the above problems occurring in the prior art, and example embodiments provide a quantum dot optical device having high-efficiency and high-purity light-emitting properties or light-receiving properties, in which the light-emitting area or light-receiving area of the device is increased because the device has a periodic projection structure on the light-emitting surface thereof, which can amplify the light in a specific wavelength band by adjusting the shape and period of the projection structure, and which can easily adjust the density and thickness of a quantum dot using the quantum dot in which the size and properties thereof are adjusted by synthesizing the quantum dot using a chemical method.

Example embodiments provide a quantum dot optical device which can be used as a light-emitting device for displays, illumination devices, backlight units, and the like.

Example embodiments provide a quantum dot optical device which is used as a light-receiving device for solar cells, photodetectors, sensor, and the like.

An aspect of example embodiments provides a quantum dot optical device, including a substrate, a hole injection electrode, a hole transport layer, a quantum dot luminescent layer, an electron transport layer, and an electron injection electrode, wherein a light-emitting surface of the device has a periodical projection structure.

Another aspect of example embodiments provides a quantum dot optical device, wherein the quantum dot optical device is a light-emitting device, such as a display device, an illumination device, a backlight unit, or the like.

A further aspect of example embodiments provides a quantum dot optical device, wherein the quantum dot optical device is a light-receiving device, such as a solar cell, a photodetector, a sensor, or the like.

### BRIEF DESCRIPTION OF THE DRAWINGS

Example embodiments will be more clearly understood from the following detailed description taken in conjunction with the accompanying drawings, in which:

FIG. 1 is a schematic sectional view showing a quantum dot optical device according to a first embodiment;

FIG. 2 is a schematic sectional view showing a quantum dot optical device according to a modification of the first embodiment;

FIG. 3 is a schematic sectional view showing a quantum dot optical device according to a second embodiment;

FIG. 4 is a schematic sectional view showing a quantum dot optical device according to a modification of the second embodiment;

FIG. 5 is a schematic sectional view showing a quantum dot optical device according to a third embodiment;

FIG. 6 is a schematic sectional view showing a quantum dot optical device according to a modification of the third embodiment;

FIG. 7 is a schematic sectional view showing a quantum dot optical device according to a fourth embodiment;

FIG. 8 is a view showing a process of manufacturing a quantum dot optical device according to a fourth embodiment;

FIG. 9 is a schematic sectional view showing a quantum dot optical device according to a fifth embodiment;

FIG. 10 is a graph showing the results of comparing a simulation of the light-emitting characteristics of a quantum dot optical device in which a triangular projection structure is periodically formed on a substrate with a simulation of the light-emitting characteristics of a quantum dot optical device in which a triangular projection structure is not formed on a substrate; and

FIG. 11 is a graph showing the results of comparing a simulation of the light-emitting characteristics of a quantum dot optical device in which triangular and trapezoidal projection structures are periodically formed on a substrate with a simulation of the light-emitting characteristics of a quantum dot optical device in which a projection structure is not formed on a substrate.

### DESCRIPTION OF THE PREFERRED EMBODIMENTS

Hereinafter, preferred embodiments of example embodiments will be described in detail with reference to the attached drawings.

Reference now should be made to the drawings, in which the same reference numerals are used throughout the different drawings to designate the same or similar components.

An aspect of example embodiments provides a quantum dot optical device, including a substrate, a hole injection electrode, a hole transport layer, a quantum dot luminescent layer, an electron transport layer, and an electron injection electrode, wherein a light-emitting surface of the device has a periodical projection structure.

In the quantum dot optical device of example embodiments, the term “light-emitting surface” is defined as a surface from which light is emitted. That is, when light is emitted from a substrate, the surface of the substrate is the light-emitting surface. In contrast, when light is emitted from the opposite side of the substrate, the surface of the electron injection electrode or hole injection electrode is the light-emitting surface.

When a projection structure is formed on the light-emitting portions or light-receiving portions of such a quantum dot optical device, the light-emitting area or light-receiving area thereof is increased, and the light in a specific wavelength band can be amplified depending on the shape and period of the projection structure, thus obtaining a light-emitting device or light-receiving device having high efficiency. In this case, the shape and period of the projection structure may be designed according to the light-emitting wavelength of a quantum dot.

The shape of the longitudinal section of the projection structure may include, but is not limited to, a triangle, trapezoid, semicircle, and a mixed shape thereof.

In example embodiments, the triangular projection structure may have, but is not limited to, a height of 300 to 1000 nm and a base length of 300 to 1000 nm.

Further, in example embodiments, the trapezoidal projection structure may have, but is not limited to, a height of 300 to 1000 nm, a base length of 300 to 1000 nm, and a top length of 1 to 1000 nm.

Further, in example embodiments, the semicircular projection structure may have, but is not limited to, a radius of 300 to 1000 nm.

However, the period, base length, top length, height and radius of the projection structure may be changed depending on the wavelength band desired to be amplified or the kind of material of the projection structure.

In the projection structure of example embodiments, the term “period” is defined as the distance between peaks. That is, the period of the projection structure may be represented by Equation 1 below:

b=λ/\sqrt{n} (1)

in which b is a period of projection, λ is a luminescent wavelength of a quantum dot, and n is a refractive index of a projection structure forming material.

According to an embodiment of example embodiments, the periodical projection structure may be formed on the substrate.

This projection structure may be formed by layering a layer, on which a projection structure is previously formed, on a substrate, which is a light-emitting unit, or by additionally layering a layer on a substrate and then etching the layer.

According to another embodiment of example embodiments, the periodical projection structure may be formed on the electron injection electrode or the hole injection electrode.

Such a projection structure may be formed by layering a layer, on which a projection structure is previously formed, on an electron injection electrode or a hole injection electrode, which is a light-emitting unit, or by additionally layering a layer on an electron injection electrode or a hole injection electrode and then etching the layer.

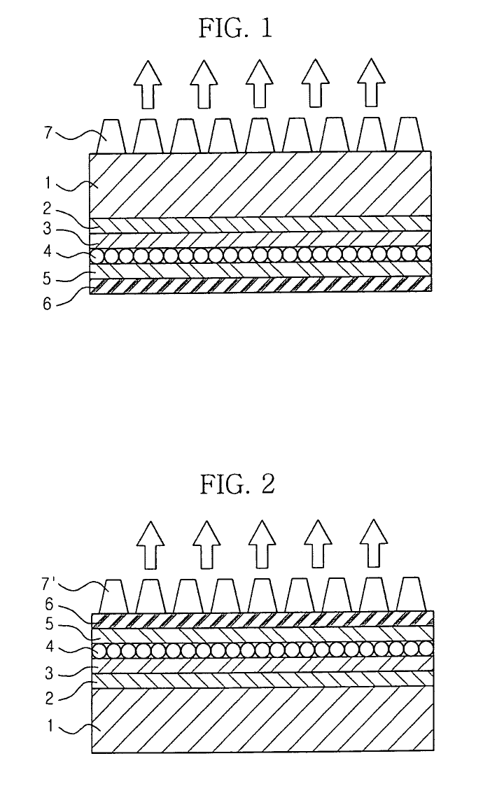

FIG. 1 shows a quantum dot optical device manufactured by sequentially layering a substrate 1, a hole injection electrode 2, a hole transport layer 3, a quantum dot luminescent layer 4, an electron transport layer 5 and an electron injection electrode 6 and then forming a trapezoidal is projection structure 7 on the substrate 1, according to a first embodiment of example embodiments. In this case, light is emitted in the direction of the arrow.

FIG. 2 shows a quantum dot optical device manufactured by layering each of the layers as shown in FIG. 1 and then forming a trapezoidal projection structure 7′ on the electron injection electrode 6, rather than the substrate 1, according to a modification of the first embodiment of example embodiments. In this case, light is also emitted in the direction of the arrow, and thus the light is amplified in a specific wavelength band depending on the shape and period of the projection structure.

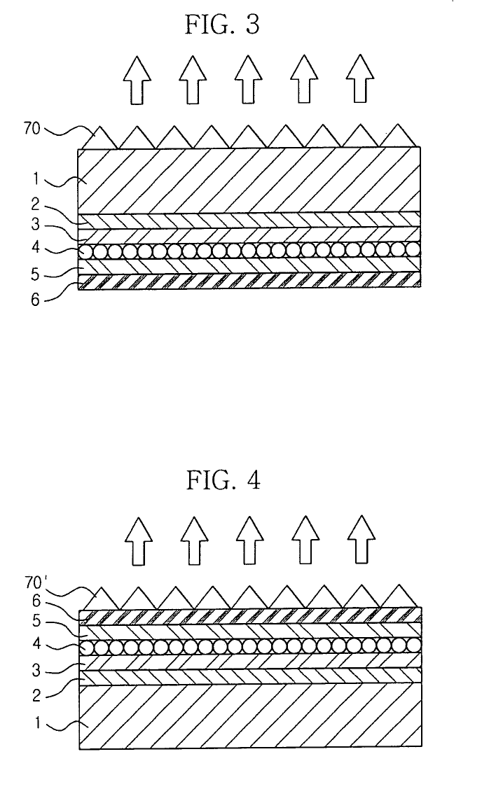

FIG. 3 shows a quantum dot optical device in which a triangular projection structure 70 is formed on the substrate 1, according to a second embodiment of example embodiments, and FIG. 4 shows a quantum dot optical device in which a triangular projection structure 70′ is formed on the electron injection electrode 6, rather than the substrate 1, according to a modification of the second embodiment of example embodiments. In this case, light is emitted in the direction of the arrow.

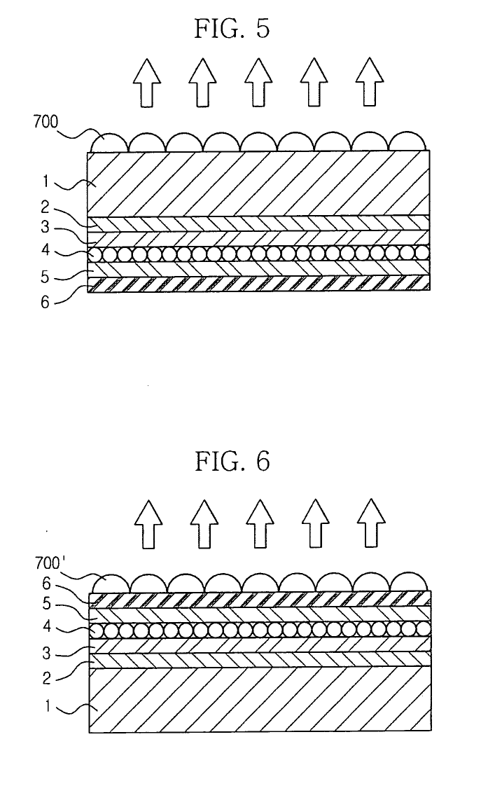

FIG. 5 shows a quantum dot optical device in which a semicircular projection structure 700 is formed on the substrate 1, according to a third embodiment of example embodiments, and FIG. 6 shows a quantum dot optical device in which a semicircular projection structure 700′ is formed on the electron injection electrode 6, rather than the substrate 1, according to a modification of the third embodiment of example embodiments. In this case, light is emitted in the direction of the arrow.

As further modifications of the optical devices shown in FIGS. 2, 4 and 6, example embodiments may provide a quantum dot optical device in which the upper and lower parts of a hole injection electrode 2, a hole transport layer 3, a quantum dot luminescent layer 4, an electron transport layer 5 and an electron injection electrode 6 are layered in the opposite direction. In this case, a projection structure may be formed on the hole injection electrode 2 in the form of a trapezoid, triangle, semicircle or a mixed shape thereof.

The projection structure may be formed of a material selected from among transparent organic materials, having high durability while not absorbing the emitted light, consisting of quartz, glass, and PDMS (polydimethylsiloxane), but is not limited thereto.

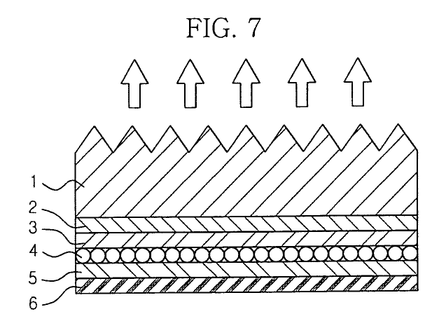

A fourth embodiment of example embodiments may provide a quantum dot optical device in which the periodical projection structure is integrally formed with the substrate. This quantum dot optical device is shown in FIG. 7.

FIG. 7 shows a quantum dot optical device manufactured by sequentially layering a substrate 1, a hole injection electrode 2, a hole transport layer 3, a quantum dot luminescent layer 4, an electron transport layer 5 and an electron injection electrode 6 and then integrally forming a triangular projection structure with the substrate 1 using an etching method or the like, according to the fourth embodiment of example embodiments. In this case, light is emitted in the direction of the arrow.

In the quantum dot optical device shown in FIG. 7, the upper and lower parts of a hole injection electrode 2, a hole transport layer 3, a quantum dot luminescent layer 4, an electron transport layer 5 and an electron injection electrode 6 may be layered in the opposite direction.

In this case, the projection structure according to the above fourth embodiment is not particularly limited, but may be formed using the following method.

In order to integrally form a projection structure with a substrate, when a photoresist is patterned for a desired period using a mask and then etched through a chemical or dry etching process, only the portion on which there is no photoresist is etched, and thus the substrate has a periodical projection structure. In this case, if the photoresist is obliquely, rather than vertically, patterned, the etched portion of the substrate has the shape of a trapezoid or a semicircle.

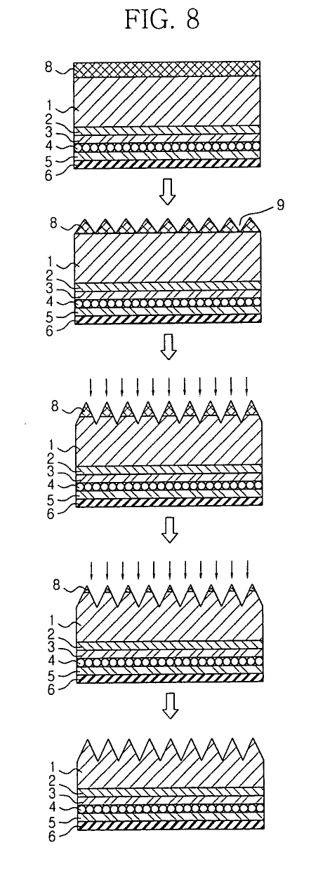

Hereinafter, the method of forming the projection structure will be described in more detail with reference to FIG. 8. In order to form the projection structure on the light-emitting surface of the quantum dot optical device according to example embodiments, first, a mask layer 8 is formed on the surface of the substrate 1. The mask layer 8 is formed by applying a photoresist layer having a desired thickness on the surface of the substrate and then hard-baking the photoresist layer.

Subsequently, holes having a desired size are formed in the mask layer at a desired period.

The holes may be formed using a conventional semiconductor lithography technology. Here, since the semiconductor lithography method is a commonly-known technology, the description of the lithography method will be omitted. The holes may be formed using AFM (atomic force microscopy), which is one example of special technologies. The AFM is a kind of SPM (scanning probe microscopy) which can grasp three-dimensional information on the surface structure of a material and can simply grasp the atom distribution of the surface of a material by Å. In the AFM, three-dimensional information on the surface of a material is obtained by two-dimensionally scanning the surface of a material using a small and sharp inspection needle called a “tip”. In the AFM, the principle in which the special distribution of the height of the inspection needle is converted into an image while the repulsive force between the inspection needle and the surface of a sample is maintained constant, that is, while the distance between the inspection needle and the surface of a sample is maintained constant, is applied.

An AFM having a single probe or an AFM having a multi-probe in which a plurality of probes is one-dimensionally or two-dimensionally arranged may be used to form holes 9 in the mask layer 8. When the tip of the probe of the AFM moves up and down at least one time, holes having a desired height can be formed in the mask layer 8. In this case, the shape of holes formed in the mask layer 8 may be changed depending on the shape of the tip. Further, in the case where the AFM having the multi-probe is used, there is an advantage in that the process of forming holes can be rapidly performed and it is possible to perform control such that holes are uniformly formed.

When holes are patterned using the AFM having a single probe or a multi-probe, it is possible to form a hole pattern having a desired height, shape and period in the mask layer.

In order to obtain a quantum dot optical device in a single wavelength band, holes may be patterned in a single period. In this case, the obtained quantum dot optical device exhibits light-emitting characteristics and/or light-receiving characteristics only with respect to light in a specific wavelength band.

The shape of the projection structure formed through an etching process may be changed depending on the depth of holes formed in the mask layer. In this case, the depth, shape, and period of the holes may be selected depending on the wavelength of light.

As shown in FIG. 8, when holes 9 having a desired depth, shape and period are formed in a mask layer and then an etching process (shown in the third and fourth drawings of FIG. 8 using arrows) is performed, a substrate, exposed through the holes 9, is etched, and thus a fine projection pattern, that is, a projection structure (triangular projection structure in FIG. 8) may be formed on the surface of the substrate. Here, the etching process may be performed using dry etching or wet etching.

In this case, when deep holes are formed in the mask layer 8, the substrate 1 is widely and deeply etched, and thus a triangular projection structure, the longitudinal section of which is a triangle (a shape similar to a circular cone or a polygonal cone having a three-dimensional shape) may be formed on the substrate, as shown in FIG. 8. In contrast, when shallow holes are formed in the mask layer 8, the substrate 1 is narrowly and shallowly etched, and thus a trapezoidal projection structure (a shape similar to a truncated cone or a truncated polygonal cone having a three-dimensional shape) may be formed on the substrate 1.

In the above etching process, when the dry etching process is performed and then the mask layer 8 is removed, the surface of the substrate, on which the triangular projection structure is formed, is exposed.

The shape of the projection structure of the quantum dot optical device according to example embodiments may be changed depending on the depth, shape, size and period of the hole formed in the mask layer and the depth of etching.

The light-emittable and/or light-receivable wavelength is determined by the period of the projection structure formed on the surface of the substrate. That is, when the period of the projection structure is long, long-wavelength light is amplified. In contrast, when the period of the projection structure is short, short-wavelength light is amplified.

Further, the luminescent field strength characteristics due to wavelength may be changed depending on the shape and period of the projection structure. Therefore, when the shape and period of the projection structure are optimized, desired wavelength and light characteristics can be realized.

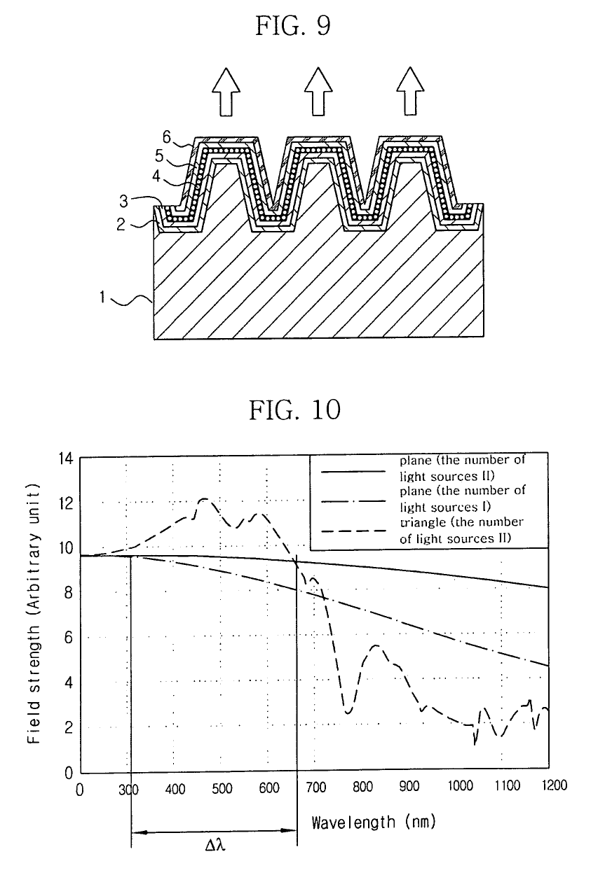

A fifth embodiment of example embodiments may provide a quantum dot optical device in which the substrate itself has a periodical projection structure, and a hole injection electrode, a hole transport layer, a quantum dot luminescent layer, an electron transport layer and an electron injection electrode are sequentially formed to conform to the projection structure of the substrate. This quantum dot optical device is shown in FIG. 9.

Referring to FIG. 9, this quantum dot optical device may be formed by sequentially layering the hole injection electrode 2, hole transport layer 3, quantum dot luminescent layer 4, electron transport layer 5 and electron injection electrode 6 along with the trapezoidal projection structure of the substrate 1. In this case, light is emitted in the direction of the arrow.

In the quantum dot optical device shown in FIG. 9, the layers constituting the quantum dot optical device may be oppositely layered. That is, this quantum dot optical device may be formed by sequentially layering the electron injection electrode, electron transport layer, quantum dot luminescent layer, hole transport layer and hole injection electrode along with the projection structure of the substrate.

The hole injection electrode of the quantum dot optical device according to example embodiments may be formed of, but is not limited to, a material selected from the group consisting of indium tin oxide (ITO), indium zinc oxide (IZO), carbon nano tube (CNT), nickel (Ni), platinum (Pt), gold (Au), silver (Ag), iridium (Ir), aluminum (Al), and oxides thereof, and, if possible, may be doped.

The material for forming the hole transport layer and electron transport layer of the quantum dot optical device according to example embodiments may be used in consideration of the energy band structure between the layers, adhesivity, processibility and reliability in order to effectively inject electrons and holes.

In particular, the hole transport layer of the quantum dot optical device according to example embodiments may be formed of, but is not limited to, a material selected from the group consisting of poly(3,4-ethylenedioxythiophene) (PEDOT)/polystyrene parasulfonate (PSS), poly-N-vinylcarbazole, polyphenylenevinylene, polyparaphenylene, polymethacrylate, poly(9,9-octylfluorene), poly(spiro-fluorene), N,N′-diphenyl-N,N′-bis 3-methylphenyl-1,1′-biphenyl-4,4′-diamine (TPD), N,N′-di(naphthalene-1-yl)-N-N′-diphenyl-benzidine, tris(3-methylphenylphenylamino)-triphenylamine (m-MTDATA), poly-9,9′-dioctylfluorene-co-N-(4-butylphenyl)diphenylamine (TFB), copper phthalocyanine, polyvinylcarbazole (PVK), and derivatives thereof; starburst materials; metal oxides, including TiO₂, ZnO, SiO₂, SnO₂, WO₃, ZrO₂, HfO₂, Ta₂O₅, BaTiO₃, BaZrO₃, Al₂O₃, Y₂O₃ and ZrSiO₄; and semiconductors, including CdS, ZnSe, and ZnS.

The electron transport layer of the quantum dot optical device according to example embodiments may include, but is not limited to, a material selected from the group consisting of metal oxides, including TiO₂, ZnO, SiO₂, SnO₂, WO₃, ZrO₂, HfO₂, Ta₂O₅, BaTiO₃, BaZrO₃, Al₂O₃, Y₂O₃ and ZrSiO₄; semiconductors, having an energy band gap of 2.4 eV or more, including CdS, ZnSe, and ZnS; and Alq3.

The quantum dot luminescent layer of the quantum dot optical device according to example embodiments, which is formed using a quantum dot as a light-emitting material, has excellent luminescent quantum efficiency and color purity compared to a conventional inorganic electroluminescence device, which is formed using a fluorescent material as a light-emitting material. Further, the fluorescent material in the conventional inorganic electroluminescence device has a nonuniform size distribution in the range of several hundreds of nanometers to several tens of millimeters. However, the quantum dot in the quantum dot optical device of example embodiments is a nano-sized (about 5 nm) material, and the thickness of the quantum dot luminescent layer using the quantum dot can be decreased to 1/1000 or less of the thickness of the conventional fluorescent material layer, thus decreasing the driving voltage of the device.

This quantum dot has a luminescence wavelength due to the specific characteristics of a quantum dot material. The quantum dot exhibits a quantum effect in which the luminescence wavelength of the quantum dot becomes short when the size of the quantum dot is decreased below the Bohr radius of about 10 nm. That is, since a blue shift phenomenon is exhibited as the size of the quantum dot is decreased, the luminescence wavelength region of the quantum dot can be controlled by adjusting the size of the quantum dot.

In this case, the quantum dot luminescent layer may be formed by layering quantum dots, which are synthesized using a chemical method and thus have adjusted sizes and properties, using a method selected from the group consisting of spin coating, dipping, contact printing, ink-jetting, and imprinting, but the method is not limited thereto.

For this reason, the quantum dot optical device according to example embodiments can exhibit high-efficiency and high-purity luminescence characteristics because the density and thickness of the quantum dot are easily adjusted.

The quantum dot luminescent layer according to example embodiments may include, but is not limited to, a material selected from the group consisting of a II-VI group compound semiconductor nanocrystal, a III-V group compound semiconductor nanocrystal, a IV-VI group compound semiconductor nanocrystal, a IV group compound semiconductor nanocrystal, and a mixture thereof; metal oxides, including ZnO, SiO₂, SnO₂, WO₃, ZrO₂, HfO₂, Ta₂O₅, BaTiO₃, BaZrO₃, Al₂O₃, Y₂O₃ and ZrSiO₄; and mixtures thereof.

The II-VI group compound semiconductor nanocrystal may be selected from the group consisting of two-element compounds including CdSe, CdTe, ZnS, ZnSe, and ZnTe; three-element compounds including CdSeS, CdSeTe, CdSTe, ZnSeS, ZnSeTe, ZnSTe, CdZnS, CdZnSe, and CdZnTe; and four-element compounds including CdZnSeS, CdZnSeTe, CdZnSTe, CdHgSeS, CdHgSeTe, CdHgSTe, HgZnSeS, HgZnSeTe, and HgZnSTe, but is not limited thereto.

The III-V group compound semiconductor nanocrystal may be selected from the group consisting of two-element compounds including GaN, GaP, GaAs, GaSb, InP, InAs, and InSb; three-element compounds including GaNP, GaNAs, GaNSb, GaPAs, GaPSb, InNP, InNAs, InNSb, InPAs, InPSb, and GaAlNP; and four-element compounds including GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, but is not limited thereto.

The IV-VI group compound semiconductor nanocrystal may be selected from the group consisting of two-element compounds including PbS, PbSe, and PbTe; three-element compounds including PbSeS, PbSeTe, PbSTe, SnPbS, SnPbSe, and SnPbTe; and four-element compounds including SnPbSSe, SnPbSeTe, and SnPbSTe, but is not limited thereto.

The IV group compound semiconductor nanocrystal may be selected from the group consisting of single-element compounds including Si and Ge; and two-element compounds including SiC and SiGe, but is not limited thereto.

The electron injection electrode according to example embodiments may be formed of a material selected from the group consisting of I, Ca, Ba, Ca/Al, Al, Mg, and an Ag—Mg alloy, but is not limited thereto.

FIG. 10 is a graph showing the results of comparing a simulation of the light-emitting characteristics of a quantum dot optical device (represented by a dashed line) in which a triangular projection structure is periodically formed on a substrate with a simulation of the light-emitting characteristics of a quantum dot optical device (represented by a solid line) in which a projection structure is not formed on a substrate, and thus the surface of the substrate is planar, and the number of light sources is II, and a simulation of the light-emitting characteristics of the quantum dot optical device (represented by a dashed dot line), in which the surface of the substrate is planar and the number of light sources is I. In FIG. 10, the horizontal axis shows luminescence wavelengths (nm), and the vertical axis shows luminescence field strengths of arbitrary unit depending on the wavelengths.

As shown in FIG. 10, it was found that the luminescence field strengths depending on the wavelengths of the quantum dot optical device, in which the surface of the substrate is planar and the number of light sources is I (here, the number of light sources I is ½ of the number of light sources II), are stronger than those of the quantum dot optical device in which the surface of the substrate is planar and the number of light sources is II. Further, it was found that the luminescence field strengths of the quantum dot optical device in which a triangular projection structure is formed on the substrate are amplified to 20˜30% of those of the quantum dot optical device in which the surface of the substrate is planar.

Accordingly, it is expected that the luminescence field strengths of the quantum dot optical device will be amplified two times or more in the case in which the number of light sources is adjusted in consideration of the surface area of the substrate, and the simulation of the light-emitting characteristics of the quantum dot optical device is enlarged and shown in three dimensions.

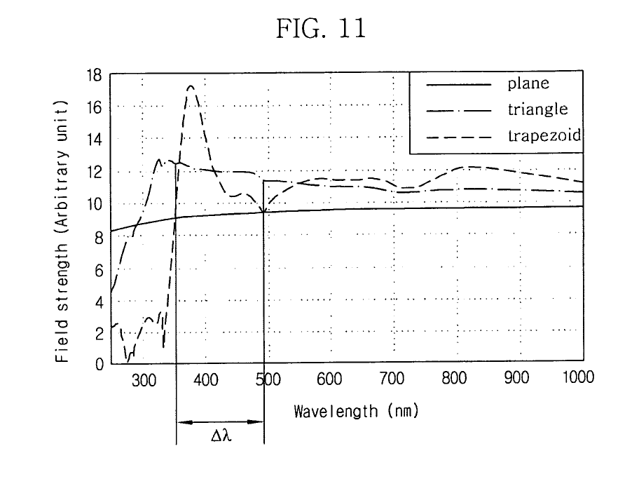

FIG. 11 is a graph showing the results of comparing a simulation of the light-emitting characteristics of a quantum dot optical device (represented by a dashed dot line), in which a triangular projection structure is periodically formed on a substrate, and a simulation of the light-emitting characteristics of a quantum dot optical device (represented by a dashed line), in which a trapezoidal projection structure is periodically formed on a substrate, with a simulation of the light-emitting characteristics of a quantum dot optical device (represented by a solid line), in which no projection structure is formed on a substrate and thus the surface of the substrate is planar. In FIG. 11, the horizontal axis shows luminescence wavelengths (nm), and the vertical axis shows luminescence field strengths of arbitrary unit depending on the wavelengths.

Referring to FIG. 11, it was found that the luminescence efficiency due to the increase of light-emitting area and the selectivity of the wavelength band are improved more in the quantum dot optical device in which a triangular projection structure is periodically formed on the substrate 1 than in the quantum dot optical device in which the surface of the substrate is planar, and more in the quantum dot optical device in which a trapezoidal structure is periodically formed on the substrate 1 than in which a triangular projection structure is periodically formed on the substrate 1. In this case, if the period and size of the projection structure is changed, a peak value, which is the wavelength band within which luminescence efficiency is exhibited at a predetermined value or more, can move, and the magnitude of the peak value can also change.

The results, shown in FIG. 10, are the results of the simulation of a two-dimensional projection structure model. Therefore, when the simulation is three-dimensionally enlarged, the luminescence efficiency and the selectivity of the wavelength band will be further effective.

The quantum dot optical device according to example embodiments can be usefully applied to light-emitting devices, such as high-efficiency display devices, illumination devices, backlight units, and the like, due to the amplification effect in a specific wavelength.

Further, the quantum dot optical device according to example embodiments can be usefully applied to light-receiving devices, such as solar cells, photodetectors, sensors, and the like, because it exhibits light-receiving characteristics when the bias varies.

According to example embodiments, the quantum dot optical device can increase a light-emitting area or a light-receiving area and can increase the brightness and luminescence efficiency of a light-emitting device because it has a periodical projection structure formed on a substrate. In this case, since the projection structure can amplify the light in a specific wavelength band, high-efficiency and high-purity light-emitting or light-receiving characteristics can be exhibited. Further, in the quantum dot optical device, since a quantum dot, which is synthesized using a chemical method and thus has adjusted size and properties, is used as a material for a luminescent layer, the quantum dot optical device has excellent luminescence efficiency and color purity, the density and thickness of the quantum dot are easily adjusted, and the method for increasing the luminescence efficiency thereof is convenient, thus increasing economic efficiency. Further, the quantum dot optical device according to example embodiments can be usefully applied to light-emitting devices, such as high-efficiency display devices, illumination devices, backlight units, and the like, and light-receiving devices, such as solar cells, photodetectors, sensors, and the like.

As described above, although the preferred embodiments of example embodiments have been disclosed for illustrative purposes, those skilled in the art will appreciate that various modifications, additions and substitutions are possible, without departing from the scope and spirit of the invention as disclosed in the accompanying claims.

What is claimed is:

1. A quantum dot optical device, comprising:
a substrate, a hole injection electrode, a hole transport layer, a quantum dot luminescent layer, an electron transport layer, and an electron injection electrode,
wherein a light-emitting surface of the device has a periodical projection structure.

2. The quantum dot optical device according to claim 1, wherein the periodical projection structure is formed on the substrate.

3. The quantum dot optical device according to claim 1, wherein the periodical projection structure is formed on the electron injection electrode or the hole injection electrode.

4. The quantum dot optical device according to claim 1, wherein the periodical projection structure is integrally formed with the substrate.

5. The quantum dot optical device according to claim 1, wherein the substrate itself has a periodical projection structure, and the hole injection electrode, the hole transport layer, the quantum dot luminescent layer, the electron transport layer and the electron injection electrode are sequentially formed to conform to the projection structure of the substrate.

6. The quantum dot optical device according to any one of claims 1 to 5, wherein a longitudinal section of the periodical projection structure is a triangle, a trapezoid, a semicircle, or a mixed shape thereof.

7. The quantum dot optical device according to claim 2 or 3, wherein the projection structure is formed of a material selected from among transparent organic materials consisting of quartz, glass, and PDMS (polydimethylsiloxane).

8. The quantum dot optical device according to claim 6, wherein, in the triangular projection structure, a ratio of height (h) to base length (l) in a triangle is in a range of 0.1 to 3.

9. The quantum dot optical device according to claim 6, wherein the trapezoidal projection structure has a height of 300 to 1000 nm, a base length of 300 to 1000 nm, and a top length of 1 to 1000 nm.

10. The quantum dot optical device according to claim 6, wherein the semicircular projection structure has a radius of 300 to 1000 nm.

11. The quantum dot optical device according to claim 6, wherein a period of the projection structure is represented by Equation 1 below:
b=λ/\sqrt{n} (1)
in which b is a period of projection, λis a luminescent wavelength of a quantum dot, and n is a refractive index of a projection structure forming material.

12. The quantum dot optical device according to claim 1, wherein the hole injection electrode is formed of a material selected from the group consisting of indium tin oxide (ITO), indium zinc oxide (IZO), carbon nanotube (CNT), nickel (Ni), platinum (Pt), gold (Au), silver (Ag), iridium (Ir), aluminum (Al), and oxides thereof.

13. The quantum dot optical device according to claim 1, wherein the hole transport layer comprises a material selected from the group consisting of poly(3,4-ethylenedioxythiophene) (PEDOT)/polystyrene parasulfonate (PSS), poly-N-vinylcarbazole, polyphenylenevinylene, polyparaphenylene, polymethacrylate, poly(9,9-octylfluorene), poly(spiro-fluorene), N,N′-diphenyl-N,N′-bis 3-methylphenyl-1,1′-biphenyl-4,4′-diamine (TPD), N,N′-di(naphthalene-1-yl)-N-N′-diphenyl-benzidine, tris (3-methylphenylphenylamino)-triphenylamine (m-MTDATA), poly-9,9′-dioctylfluorene-co-N-(4-butylphenyl) diphenylamine (TFB), copper phthalocyanine, polyvinylcarbazole (PVK), and derivatives thereof; starburst materials; metal oxides, including TiO₂, ZnO, SiO₂, SnO₂, WO₃, ZrO₂, HfO₂, Ta₂O₅, BaTiO₃, BaZrO₃, Al₂O₃, Y₂O₃ and ZrSiO₄; and semiconductors, including CdS, ZnSe, and ZnS.

14. The quantum dot optical device according to claim 1, wherein the quantum dot luminescent layer is formed by layering quantum dots, which are synthesized using a chemical method and thus have adjusted sizes and properties, using a method selected from the group consisting of spin coating, dipping, contact printing, ink-jetting, and imprinting.

15. The quantum dot optical device according to claim 1, wherein the quantum dot luminescent layer comprises a quantum dot selected from the group consisting of a II-VI group compound semiconductor nanocrystal, a III-V group compound semiconductor nanocrystal, a IV-VI group compound semiconductor nanocrystal, a IV group compound semiconductor nanocrystal, and mixtures thereof; and metal oxides, including ZnO, SiO₂, SnO₂, WO₃, ZrO₂, HfO₂, Ta₂O₅, BaTiO₃, BaZrO₃, Al₂O₃, Y₂O₃, ZrSiO₄, and mixtures thereof.

16. The quantum dot optical device according to claim 15, wherein the II-VI group compound semiconductor nanocrystal is selected from the group consisting of two-element compounds, including CdSe, CdTe, ZnS, ZnSe, and ZnTe; three-element compounds, including CdSeS, CdSeTe, CdSTe, ZnSeS, ZnSeTe, ZnSTe, CdZnS, CdZnSe, and CdZnTe; and four-element compounds, including CdZnSeS, CdZnSeTe, CdZnSTe, CdHgSeS, CdHgSeTe, CdHgSTe, HgZnSeS, HgZnSeTe, and HgZnSTe,
the III-V group compound semiconductor nanocrystal is selected from the group consisting of two-element compounds, including GaN, GaP, GaAs, GaSb, InP, InAs, and InSb; three-element compounds, including GaNP, GaNAs, GaNSb, GaPAs, GaPSb, InNP, InNAs, InNSb, InPAs, InPSb, and GaAlNP; and four-element compounds, including GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb,
the IV-VI group compound semiconductor nanocrystal is selected from the group consisting of two-element compounds, including PbS, PbSe, and PbTe; three-element compounds, including PbSeS, PbSeTe, PbSTe, SnPbS, SnPbSe, and SnPbTe; and four-element compounds, including SnPbSSe, SnPbSeTe, and SnPbSTe, and
the IV group compound semiconductor nanocrystal is selected from the group consisting of single-element compounds including Si and Ge; and two-element compounds, including SiC and SiGe.

17. The quantum dot optical device according to claim 1, wherein the electron transport layer comprises a material selected from the group consisting of metal oxides including TiO₂, ZnO, SiO₂, SnO₂, WO₃, ZrO₂, HfO₂, Ta₂O₅, BaTiO₃, BaZrO₃, Al₂O₃, Y₂O₃ and ZrSiO₄; semiconductors, having an energy band gap of 2.4 eV or more, including CdS, ZnSe, and ZnS; and Alq3.

18. The quantum dot optical device according to claim 1, wherein the electron injection electrode is formed of a material selected from the group consisting of I, Ca, Ba, Ca/Al, Al, Mg, and an Ag-Mg alloy.

19. The quantum dot optical device according to any one of claims 1 to 5, wherein the optical device is a light-emitting device.

20. The quantum dot optical device according to claim 19, wherein the light-emitting device is a display device, a illumination device, or a backlight unit.

21. The quantum dot optical device according to any one of claims 1 to 5, wherein the optical device is a light-receiving device.

22. The quantum dot optical device according to claim 21, wherein the light-receiving device is a solar cell, a photodetector, or a sensor.
